(19) United States
(12) Patent Application Publication
(10) Pub. No.: US 2026/0171886 A1
(43) Pub. Date: Jun. 18, 2026

(54) POWER CIRCUIT AND METHOD FOR ESTIMATING A CURRENT

(71) Applicant: Renesas Electronics America Inc., Milpitas, CA (US)

(72) Inventors: Benoit LABBE, Harlow (GB); Claudio COLLURA, Harlow (GB); Gwilym Francis LUFF, Harlow (GB)

(73) Assignee: Renesas Electronics America Inc., Milpitas, CA (US)

(21) Appl. No.: 18/985,760

(22) Filed: Dec. 18, 2024

(51) Int. Cl. H02M 1/00; G01R 19/25; H02M 1/44; H03M 3/00

(52) U.S. Cl. CPC H02M 1/0009; G01R 19/2513; H02M 1/44; H03M 3/458

(57) ABSTRACT

A power circuit includes one or more power supplies controlled by a controller, a sensor, and a filter. Each power supply comprises an electrical component adapted to store energy. The sensor senses a first current having a first bandwidth through the electrical component. The filter filters a signal based on the first current to obtain a filtered current having a second bandwidth that is less than the first bandwidth. The controller is configured to process the filtered current to generate an estimated current having a third bandwidth greater than the second bandwidth.

### FIELD

The present disclosure relates to a power circuit and method for estimating a current through an electronic component adapted to store energy. In particular, the present disclosure relates to a power circuit and method for estimating a current through an inductor.

### BACKGROUND

Power circuits typically comprise a controller configured to manage one or more individual power supplies. These one or more individual power supplies may, for example, each drive one or two phases of a buck converter. Each of the power supplies are configured to provide a current to an inductor. In order for the controller to be able to manage the power supplies efficiently, the controller requires a feedback sample current which contains information on the current that each power supply is providing to their respective inductor.

For high performance control techniques, the controller requires knowledge on the frequency dynamic of the current the power supplies provides to the inductors. The frequency dynamic range of this current can be quite large. This requires providing the controller with a high bandwidth and accurate feedback sample current. This is difficult to achieve as in most high-power power circuits, the feedback sample current is provided to the controller via printed circuit board (PCB) traces. The traces are conductive pathways etched onto the PCB substrate which introduce noise and attenuation to the feedback sample current. This degrades the bandwidth and accuracy of the information provided to the controller and key information is lost.

It is an objective of the present disclosure to address one or more of the above limitations.

### SUMMARY

According to a first aspect of the disclosure, there is provided a power circuit comprising:
one or more power supplies, wherein each power supply comprises an electrical component adapted to store energy;
a controller for controlling the one or more power supplies;
a sensor adapted to sense a first current through the electrical component, wherein the first current has a first bandwidth; and
a filter configured to receive a signal based on the first current and output a filtered current having a second bandwidth that is less than the first bandwidth;
wherein the controller is configured to process the filtered current to generate an estimated current having a third bandwidth greater than the second bandwidth.

For instance the power supplies may be switched power supplies such as buck, boost, or buck/boost converters.

Optionally, the filter is a low pass filter. For instance the low pass filter may be implemented as part of the controller or alternatively as part of a power supply.

Optionally, the low pass filter has a transfer function characterised by a pole at a predefined frequency and designed to attenuate parasitic noise present in the power circuit.

Optionally, the power circuit has parasitic poles having parasitic frequencies, and wherein the pole associated with the low pass filter is a dominant pole having a frequency lower than the parasitic frequencies.

For instance the parasitic poles may be caused by a conducting path transporting the first current.

Optionally, the dominant pole is configured to set the cutoff frequency so that the parasitic frequencies can be neglected.

Optionally, the predefined frequency of the pole is selected to be about 5 to 10 times slower than a switching frequency of the first current.

Optionally, the low pass filter comprises a sigma-delta analogue-to-digital converter.

For instance, the low pass filter may operate with a data rate having a frequency higher than the switching frequency of the first current.

Optionally, the low pass filter comprises an anti-aliasing filter coupled to the sigma-delta analogue-to-digital converter.

Optionally, wherein the first current comprises a noise component, the noise component comprising noise arising from one or more sources in the power circuit.

For instance, the noise may arise from one or more of a PCB trace, a wire and the one or more power supplies.

Optionally, wherein the third bandwidth is equal to the first bandwidth.

Optionally, wherein the controller is configured to execute an algorithm based on an observer model.

Optionally, wherein the observer model is configured using a set of data points; wherein the set of data points comprises one or more of: parameters of the filter, properties of the one or more power supplies, an input voltage for the one or more power supplies, and an output voltage for the one or more power supplies.

For instance, the parameters of the filter may include the DC-gain and the cutoff frequency (for example the DC-gain may be set to 1, and cutoff frequency=Fsw/10). The properties of the power supplies can include: voltages (in/out), duty ratios, temperature, switch resistances, control to switching delays, dead-times.

Optionally, wherein the observer model comprises a Luenberger observer model or a sliding-mode observer.

Optionally, the controller comprises a calculator for executing the algorithm, wherein the calculator is implemented with a parallel architecture, or a single stream observer architecture, or a dual stream observer architecture.

Optionally, the electrical component comprises an inductor, and wherein the first current is a first inductor current, the filtered current is a filtered inductor current, and the estimated current is an estimated inductor current.

According to a second aspect of the disclosure, there is provided a method of estimating a current through an electrical component adapted to store energy, the method comprising:
measuring a first current through the electrical component, wherein the first current has a first bandwidth;
filtering a signal based on the first current to generate a filtered current having a second bandwidth that is less than the first bandwidth; and
processing the filtered current, to generate an estimated current having a third bandwidth greater than the second bandwidth.

Optionally, wherein the third bandwidth is equal to the first bandwidth.

Optionally, wherein processing the filtered current comprises executing an algorithm based on an observer model.

Optionally, wherein the filtering is performed using a low pass filter having a transfer function characterised by a pole at a predefined frequency and designed to attenuate parasitic noise present in the power circuit.

Optionally, wherein the low pass filter comprises a sigma-delta analogue-to-digital converter.

### BRIEF DESCRIPTION OF THE DRAWINGS

The disclosure is described in further detail below by way of example only with reference to the accompanying drawings, in which:

FIG. 1 is a diagram of a power circuit according to the present disclosure;

FIG. 2A is a first example implementation of a low-pass filter for use in the power circuit of FIG. 1;

FIG. 2B is a second example implementation of a low-pass filter for use in the power circuit of FIG. 1;

FIG. 2C is a third example implementation of a low-pass filter for use in the power circuit of FIG. 1;

FIG. 2D is a fourth example implementation of a low-pass filter for use in the power circuit of FIG. 1;

FIG. 3 is a plot showing several waveforms as a function of frequency;

FIG. 4 is a diagram showing the operation principle of an algorithm executed by an observer circuit in the controller of FIG. 1;

FIG. 5A is a diagram of an observer circuit having a full parallel architecture;

FIG. 5B is a diagram of a single stream observer architecture for implementing the observer circuit;

FIG. 5C is a diagram of a dual stream observer architecture for implementing the observer circuit;

FIG. 6A is an exemplary implementation of the power circuit of FIG. 1;

FIGS. 6B and 6C show an exemplary implementation of an observer circuit for use in the power circuit of FIG. 6A;

FIG. 6D is an example implementation of a filter for use in the power circuit of FIG. 6A;

FIGS. 7A and 7B are plots showing simulation results for the power circuit using the single stream observer architecture of FIG. 5B;

FIG. 8 is a plot showing simulation results for the power circuit using the single stream observer architecture of FIG. 5B; and

FIG. 9 is a flow chart of a method of estimating a current through an electrical component adapted to store energy, such as an inductor, according to the present disclosure.

### DETAILED DESCRIPTION

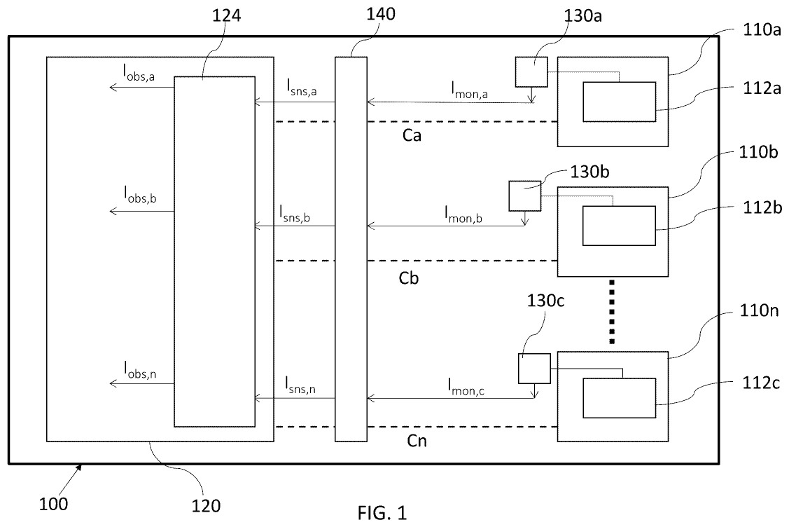

FIG. 1 is a diagram of a power circuit 100 according to the present disclosure. The power circuit 100 comprises one or more power supplies 110a, 110b, 110n and a controller 120 for controlling the one or more power supplies 110a, 110b, 110n. Whilst for the example power circuit 100 only three power supplies 110a, 110b, 110n are shown, it is understood that in alternative embodiments any number of power supplies may be used. Furthermore, whilst in the example power circuit 100 there is shown a single controller 120 for all the power supplies 110a, 110b, 110n, in alternative embodiments each power supply could have their own controller. Each power supply 110a, 110b, 110n comprises an inductor 112a, 112n, 112n. The power supplies 110a, 110b, 110n may be switched power supplies, for example a buck, a boost or a buck-boost power supply.

The power circuit 100 further comprises a plurality of sensors 130a, 130b, 130n, each sensor being configured to sense a first inductor current I_{mon,a}, I_{mon,b}, I_{mon,n} through the inductors 112a, 112b, 112n, respectively. The plurality of sensors may be implemented in ways known in the prior art, for instance, as in: “An On-Chip High-Speed Current Sensor Applied in the Current-Mode DC-DC Converter” (Wang et al. 2014; 10.1109/TPEL.2014.2302318) or “Lossless Inductor Current Sensing Method With Improved Frequency Response” (Ziegler et al. 2009; TPEL.2009.2013954). In alternative embodiments there may only be a single sensor for the one or more power supplies. Each first inductor current I_{mon,a}, I_{mon,b}, I_{mon,n} has a first bandwidth.

The power circuit 100 also includes a filter 140 configured to filter the first inductor currents I_{mon,a}, I_{mon,b}, I_{mon,n} to obtain the filtered inductor currents I_{sns,a}, I_{sns,b}, I_{sns,n}, respectively. Depending on the implementation the filter 140 may receive a signal based on the sensed first inductor current which may be the sensed first inductor current itself.

In alternative embodiments a separate filter may be provided for each power supply. Each filtered inductor current I_{sns,a}, I_{sns,b}, I_{sns,n} has a second bandwidth which is less than the first bandwidth of the first inductor current I_{mon,a}, I_{mon,b}, I_{mon,n}. The filter 140 may be, for example, a low pass filter. The first inductor current I_{mon,a}, I_{mon,b}, I_{mon,n} has a noise component. The noise component may arise from one or more sources in the power circuit. For example, the noise component may be due to the wires or PCB traces which the first inductor current I_{mon,a}, I_{mon,b}, I_{mon,n} travels along between the one or more power supplies 110a, 110b, 110n and the rest of the circuit. The noise component may also include noise due to the one or more power supplies 110a, 110b, 110n themselves. The filter 140 then filters the first inductor current I_{mon,a}, I_{mon,b}, I_{mon,n} to compensate for the noise component by introducing a dominant pole into the filtered inductor current I_{sns,a}, I_{sns,b}, I_{sns,n}. The filtering action removes most of the noise induced in the first inductor current I_{mon,a}, I_{mon,b}, I_{mon,n} and reduces the importance of the effect of the PCB trace on the feedback signal. The filtering action can be performed by adding a capacitor of a known value to the PCB trace, or by active filtering before digitalisation.

The controller 120 is configured to process the filtered inductor current I_{sns,a}, I_{sns,b}, I_{sns,n} to generate an estimated inductor current I_{obs,a}, I_{obs,b}, I_{obs,n} having a third bandwidth greater than the second bandwidth. The third bandwidth may be equal to the first bandwidth of the first inductor current I_{mon,a}, I_{mon,b}, I_{mon,n}. The controller 120 is configured to execute an algorithm based on an observer model in order to generate the estimated inductor current I_{obs,a}, I_{obs,b}, I_{obs,n}. The observer model may be, for example, a Luenberger observer model. The algorithm uses an observer model to reconstruct the first inductor current I_{mon,a}, I_{mon,b}, I_{mon,n} based on a set of data points. This set of data points comprises the filtered inductor current I_{sns,a}, I_{sns,b}, I_{sns,n} and knowledge of the operating conditions of the power circuit 100. For the algorithm to operate reliably, the filtered inductor current I_{sns,a}, I_{sns,b}, I_{sns,n} needs to have undergone filtering that suppresses the noise component comprising noise from one or more sources in the power circuit 100.

The controller 120 includes a calculator or processor 124 for executing the algorithm. The calculator or processor 124 is also referred to as the observer circuit.

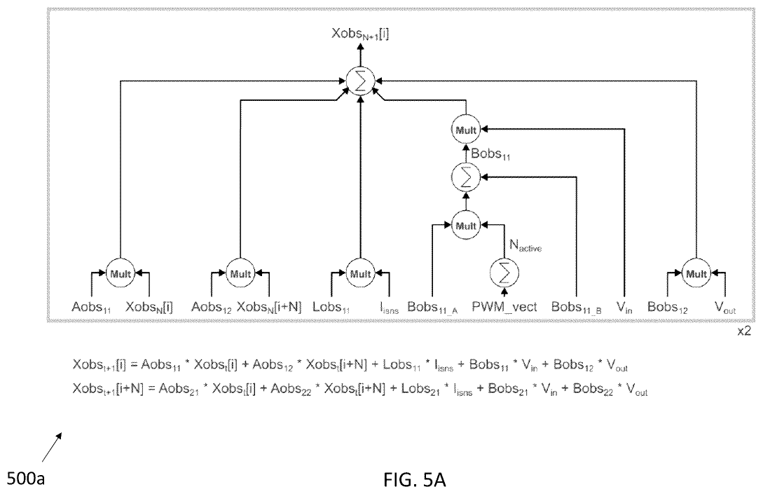

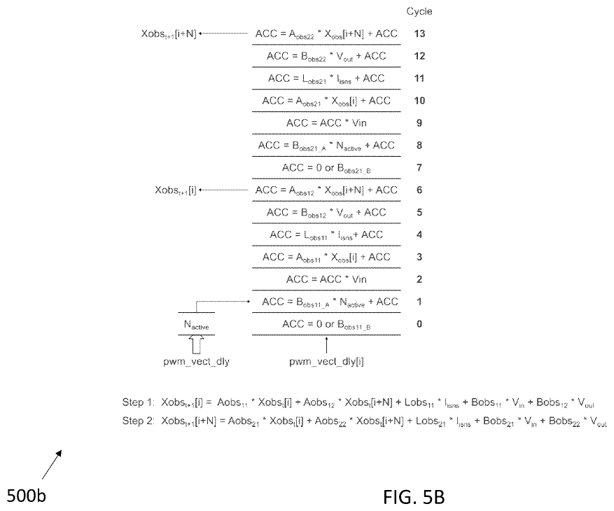

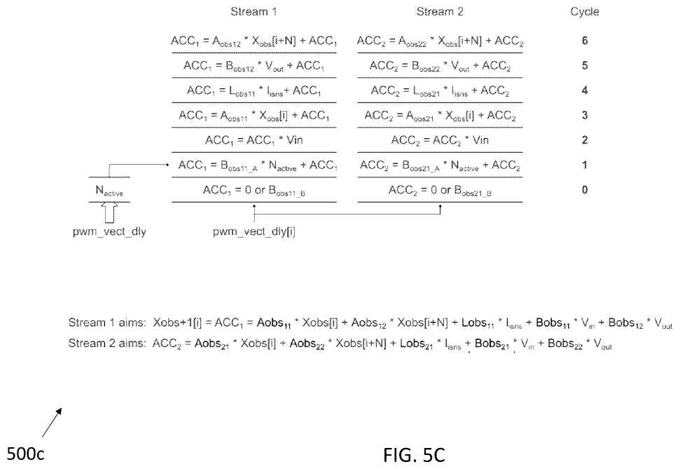

The observer circuit 124 may be implemented using different architectures. Example of potential architectures are described below in FIGS. 5A, 5B and 5C.

In operation, the sensors 130a, 130b, 130n sense the first inductor current I_{mon,a}, I_{mon,b}, I_{mon,n} generated by each of the one or more power supplies 110a, 110b, 110n. The first inductor current I_{mon,a}, I_{mon,b}, I_{mon,n} is transmitted to the controller 140 via transport means, for example a wire or a PCB trace, which adds a noise component and attenuates the various frequency components of the first inductor current I_{mon,a}, I_{mon,b}, I_{mon,n}.

The first inductor current I_{mon,a}, I_{mon,b}, I_{mon,n} undergoes filtering, either before or after it is transmitted. The filter 140 may be implemented as a low pass filter. The low pass filter 140 has transfer function characterised by a pole at a predefined frequency and designed to attenuate parasitic noise present in the power circuit. The pole, also referred to as dominant pole is chosen to attenuate the parasitic poles present in the circuit, for instance along the conducting path transporting the first current. The parasitic poles have parasitic (pole) frequencies. In the context of the present disclosure, a dominant pole is a single pole having a frequency lower than the parasitic frequencies. The difference between the frequency of the dominant pole and the parasitic frequencies should provide sufficient margin such that the gain of the system (including sensor circuit, I/Os, pcb trace, analog front-end and the filter) at the frequency of the other poles is much lower than the gain of the system at the low frequency of DC gain of the dominant pole. The notion of dominant pole is that one pole sets the cutoff frequency of the low pass filter and optionally the gain of the low pass filter so that the frequencies of other poles can be neglected (i.e. there is no signal passing-through). For the power circuit of the present disclosure, the filter 140 may have a higher order than 1 and thus multiple poles may have to be taken into account.

As such, the filtered inductor signal I_{sns,a}, I_{sns,b}, I_{sns,n} is less affected by the transport means. In other words the effects of the dominant pole eclipse the effects of the poles due to the transfer means transfer function. The filtered inductor signal I_{sns,a}, I_{sns,b}, I_{sns,n} is provided to the observer circuit 124 at the controller 120. The algorithm is based on an observer model and is partly configured based on the specifics of the dominant pole, in other words the frequency of the dominant pole. The algorithm has knowledge of various system inputs of the power supplies 110a, 110b, 110n and generates the estimated inductor current I_{obs,a}, I_{obs,b}, I_{obs,n}. The system inputs may be, for example, the output voltage Vₒ, the input voltage Vᵢₙ and the control signals Ca, Cb and Cn. Each estimated inductor current I_{obs,a}, I_{obs,b}, I_{obs,n} is a reconstruction the first inductor current I_{mon,a}, I_{mon,b}, I_{mon,n} based on the known state variables and the filtered inductor signal I_{sns,a}, I_{sns,b}, I_{sns,n}.

In turn the estimated inductor currents I_{obs,a}, I_{obs,b}, I_{obs,n} can be used to generate the control signals Ca, Cb, Cn controlling the power supplies 110a, 110b, 110c, respectively.

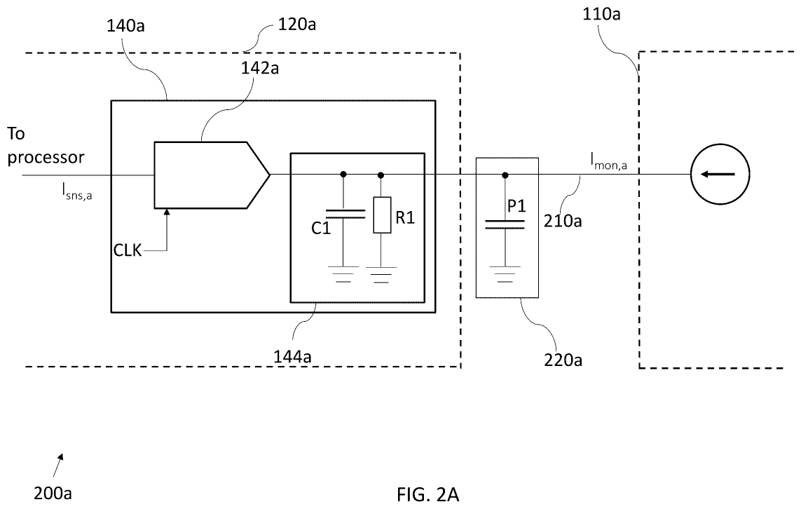

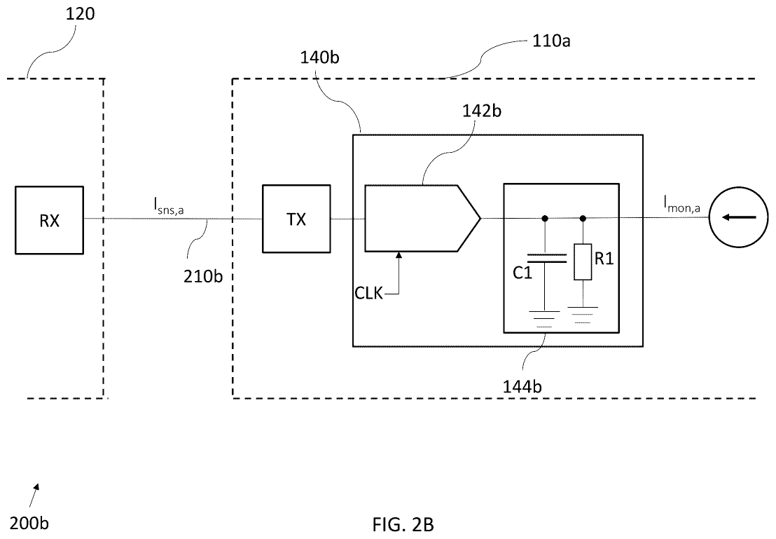

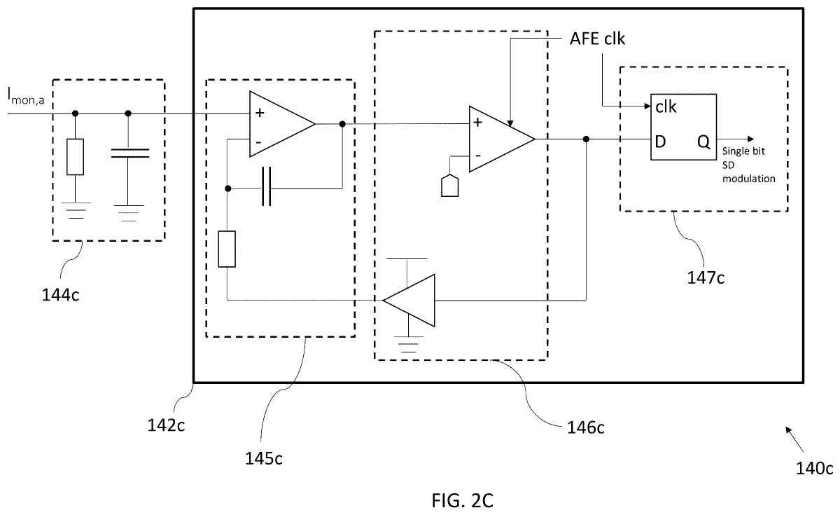

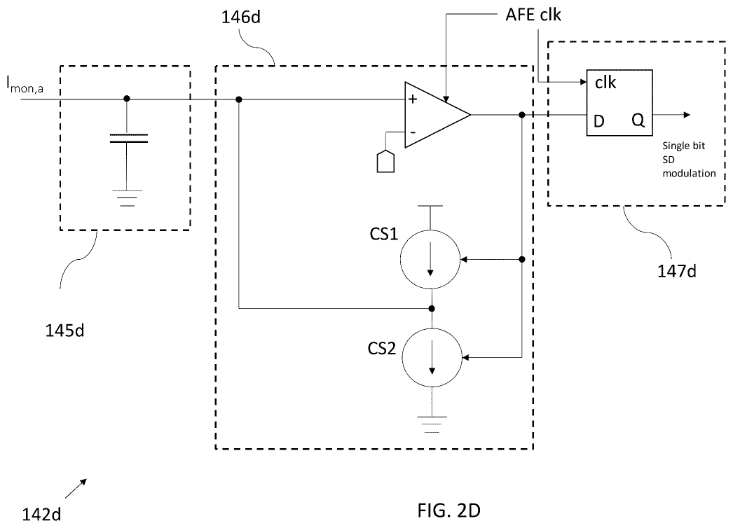

FIG. 2A is a diagram 200a showing a filter 140a for use in the power circuit 100 of FIG. 1. In this example the filter 140a is a low pass filter. The low pass filter 140a comprises a sigma-delta analogue-to-digital converter (SDADC) 142a and an anti-aliasing filter and gain setting 144a. In the example 200a, the low pass filter 140a is part of the controller 120a. The SDADC 142a has an input for receiving a clock signal CLK. The clock signal CLK is used for sequencing the operation of the SDADC 142a and the controller 120. The anti-aliasing filter and gain setting 144a is formed of a capacitor C1 in parallel with a resistor R1. In the example implementation 200a, only a single power supply 110a is shown. It is to be understood that this example implementation 200a can be implemented with any of the one or more power supplies 110a, 110b, 110n of the power circuit 100. The SDADC 142a is configured to add a dominant pole into the filtered inductor current I_{sns,a}.

The first inductor current I_{mon,a} is generated and sensed and transmitted via transport means 210a to the controller 120a. In the example implementation 200a, the transport means 210a is a PCB trace. However, in alternative embodiments the transport means may be, for example, a wire or other conductive path. The PCB trace 210a coupling the controller 120a and the power supply 110a adds multiple parasitic poles 220a of unknown value P1. The capacitance of the trace 210a is one of the sources of the parasitic poles 220a. The SDADC 142a introduces a pole referred to as the dominant pole of the filter. Hence, the effects of the PCB trace 210a become attenuated. The SDADC 142a has a dual role. Firstly, it digitises the filtered inductor current I_{sns,a} to submit it to the algorithm. Secondly, it introduces the dominant pole. The anti-aliasing filter and gain setting stage 144a is useful for better performance of the SDADC 142a but not essential if in alternative embodiments other types of ADC are used.

FIG. 2B is a second example implementation 200b of a filter 140b for use in the power circuit 100 of FIG. 1. The filter 140b is a low pass filter. The low pass filter 140b comprises SDADC 142b and an anti-aliasing filter and gain setting 144b. In the example implementation 200b, the low pass filter 140b is implemented as part of the power supply 110a. The low pass filter 140b is the same as the low pass filter 140a of FIG. 2A, except in the example implementation 200b, the filter 140b is part of the power supply 110a. Hence the description of the SDADC and anti-aliasing filter and gain setting will not be repeated here. It is to be understood that this example implementation 200a can be implemented with any of the one or more power supplies 110a, 110b, 110n of the power circuit 100.

In this second example implementation 200b, the low pass filter 140b accounts for the noise due to transmission along the PCB trace 210b before transmission of the current. A transmitter TX is then used to send the filtered current I_{sns,a}, to a receiver RX provided in the controller, where the filtered current can be processed.

FIG. 2C is a third example implementation of a filter 140c for use in the power circuit 100 of FIG. 1. The filter 140c is a low pass filter. The low pass filter 140c comprises a SDADC 142c and an anti-aliasing filter and gain setting 144c. In the present disclosure, a high frequency noise, coupled along the PCB trace 210b or at the input of the SDADC 142c, would appear as a signal in the signal frequency band due to the aliasing phenomenon. Due to the SDADC 142c, the sampling frequency may be relatively high. Thus the anti-aliasing filter is realised as one of the high-order poles that is made negligible by the dominant pole. The anti-aliasing filter is provided to remove the issue of aliasing of high-frequency noise. The SDADC 142c is implemented as a voltage mode modulator. The SDADC 142c comprises a modulation integrator 145c, a sampling and DAC 146c and a synchroniser 147c. In this example implementation, the modulation integrator 145c integrates the error between the input signal and the “DAC” output formed by the buffer at the bottom of the sampling and DAC 146c. If the DAC output is lower than the input signal, the output signal of the modulation integrator 145c rises. Otherwise, the output voltage of the modulation integrator 145c falls. The sampling and DAC 146c samples the output of the modulation integrator 145c. If the integrated error is higher than the reference connected to the negative input of the comparator, the comparator output is set high and the DAC output is set to high (or low otherwise). Doing so, the DAC average output is maintained equal to the input signal.

FIG. 2D is a fourth example implementation of a filter 142d for use in the power circuit 100 of FIG. 1. The filter 142d is a low pass filter. The low pass filter is a SDADC 142d comprising a modulation integrator 145d, a sampling and DAC 146d and a synchroniser 147d. The SDADC 142d is implemented as a current mode modulator. In this example implementation, the modulation integrator 145d integrates the input current and the DAC current. The DAC is formed by a charge pump, presented as a first current source CS1 and a second current source CS2. Depending on the sampling comparator output state, either the first current source CS1 is active or the second current source CS2 is active. If the voltage across the modulation integrator 145d is higher than the negative input of the comparator, then the DAC is not pulling enough current, and thus the comparator activates the second current source CS2. If the voltage across the modulation integrator 145d is lower than the negative input voltage of the comparator, the charge pump is not pushing enough current to equalise the current from the first inductor current I_{mon,a} thus the first current source CS1 is activated. On average, the current delivered by the charge pump equals the first inductor current I_{mon,a}.

The low pass filters described with reference to FIGS. 2A-2D may be configured to operate with a data rate having a frequency higher than the switching frequency of the first current.

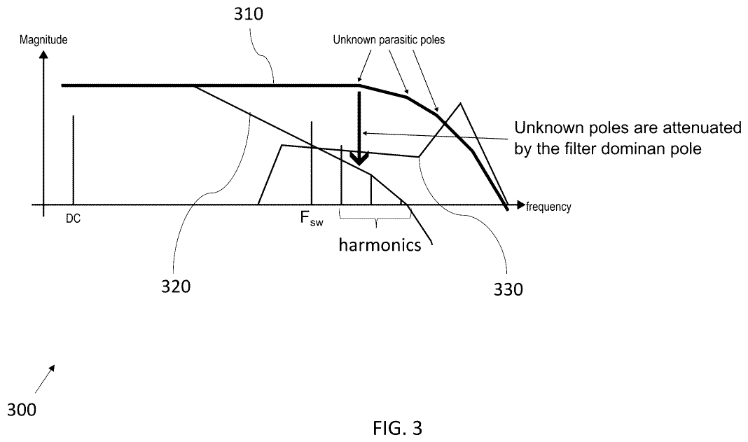

FIG. 3 is a plot showing several bode diagrams (magnitude as a function of frequency). The vertical lines represent the spectrum of the first inductor current I_{mon,a} that includes DC frequency, switching frequency Fsw and the harmonics. The bode diagram 310 shows the gain over frequency of the transmission channel. The bode diagram 320 is the gain over frequency of the transmission channel plus the filter. The bode diagram 330 is an example spectrum of the switching and induced noise.

The amplitude of the first inductor current 310 is constant at low frequency and starts decreasing above a certain frequency. This is due to unknow parasitic poles.

A pole frequency is the frequency at which the transfer function of a system approaches infinity.

The filter used to filter the first inductor current has poles and zeros. These characteristics of the filter provide information about how the system will respond to signals with different input frequencies. The filter used has a dominant pole provided at a frequency that will attenuate the parasitic poles.

The frequency range that the switching frequency Fsw and its harmonics lie in are known, hence the form that the dominant pole should take can be calculated. Deciding the location of the dominant pole in the filtered inductor current I_{sns,a}, I_{sns,b}, I_{sns,n} is based on the expected parasitics of the power circuit 100, the switching frequency Fsw of the first inductor current I_{mon,a}, I_{mon,b}, I_{mon,n}, and the bandwidth of the first inductor current. By tuning the parameters of the filter 140, the shape and behaviour of the dominant pole can be changed.

Experimentally, it has been assessed that the dominant pole should be at a frequency of at least 5 to 10 times slower than the switching frequency Fsw of the first inductor current I_{mon,a}, I_{mon,b}, I_{mon,n}. This allows for a trade-off between the information shed by the filter 140 and the performance of the algorithm whilst ensuring that the effects of the noise components become marginal. The information from the filter 140 is a low-pass filtered measurement of the first inductor current I_{mon,a}, I_{mon,b}, I_{mon,n}. For example, if the switching frequency is at 1 MHz, then the dominant pole should be in the range of 100-200 Khz for optimal performance.

The dominant pole should take a form such that it overcomes the effect of the parasitic poles. Implementing the dominant pole results in some loss of the first inductor current I_{mon,a}, I_{mon,b}, I_{mon,n}, such that the filtered inductor current I_{sns,a}, I_{sns,b}, I_{sns,n} has a lower bandwidth than the first inductor current I_{mon,a}, I_{mon,b}, I_{mon,n}. However, the lost parts of the first inductor current I_{mon,a}, I_{mon,b}, I_{mon,n} can be reconstructed using the algorithm based on an observer model.

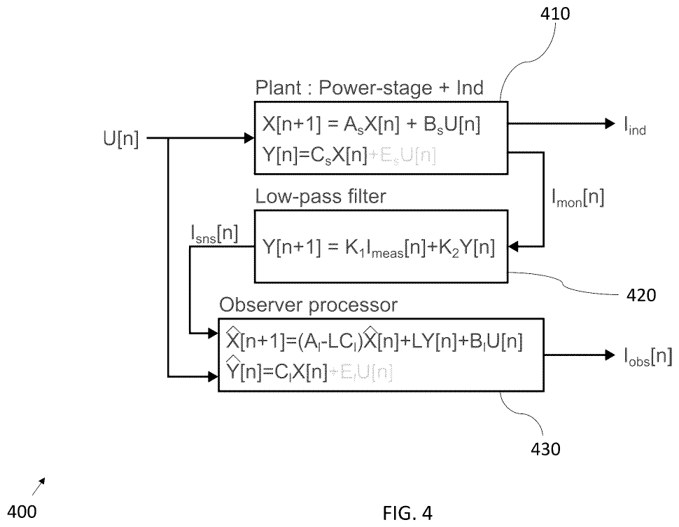

FIG. 4 is a diagram showing the operation principle 400 of the algorithm executed by the controller 120 of FIG. 1. In this example, the algorithm is based on an observer model. For example, the observer model could be a Luenberger observer model or a sliding-mode observer.

The operation principle 400 comprises three blocks. The first block is the plant 410 which is a mathematical representation of the one or more power supplies 110a, 110b, 110n. The second block is the filter block 420 which is a mathematical representation of the filter 140. In this example, the filter 140 is a low pass filter. The final block is the observer processor 430 which provides the observer model performed to generate the estimated inductor current I_{obs}[n]. The observer model is configured using a set of data points. The set of data points comprises the parameters of the filter 140, properties of the one or more power supplies 110a, 110b, 110n as well as an input and/or output voltage for the one or more power supplies 110a, 110b, 110n. The observer model uses this set of data points to recreate the bandwidth information of the first inductor current I_{mon,a}, I_{mon,b}, I_{mon,n}.

The variables in each of the blocks 410, 420 and 430 are defined as follows. The variable X is the state vector of the inductor seen as a system. The state vector X comprises the first inductor current Iₘₒₙ[n] and the filtered inductor current Iₛₙₛ[n]. The variables As and Bs are the state transition matrix and input matrix of the system, whilst the variable U is the input vector of the system. The variable Cₛ is the output matrix and Es is the input-to-output matrix of the system. Note that the variables of a state observer are commonly denoted by a “hat”, \hat{ }, to distinguish them from the variables of the equations satisfied by the physical system. In practice, the hat denotes the observer's estimation of that variable. For instance, if the observer model is a Luenberger observer, the algorithm operates by solving the equation:

$$\hat{X} [ n + 1 ] = ( {A}_{l} - L {C}_{l} ) \hat{X} [ n ] + LY [ n ] + {B}_{l} U [ n ]$$

Where the vector L has values dependent on the desired placement of the eigenvalues of the state observer. The variable Y is the filtered inductor current Iₛₙₛ[n] with the known dominant pole and the variable U is the input vector comprising the output voltage and the switching node voltage of the one or more power supplies. The observer is stable if the eigenvalues of (Aₛ-LCₛ) are within the unit circle.

In this FIG. 4 the variables As (in box 410) and Al (in box 430) are different to show that the system has parameters that may not be very accurately known by the observer. For instance, an inductance value L, is known withing some tolerance, and generally not calibrated. Furthermore the actual value can change depending on the conditions while the observer has to assume a fixed value that isn't too far off the actual value.

In preferred embodiments, the algorithm uses knowledge of the PWM control signals Cₐ, C_{b}, Cₙ and input voltage to the one or more power supplies 110a, 110b, 110c to estimate the voltage of the switching nodes driving the inductors 112a, 112b, 112c. The calculator or observer circuit 124 for executing the algorithm may be implemented as a digital circuit or as an analogue circuit. Various architectures can be envisaged.

FIG. 5A is a diagram of first example implementation of an observer circuit 500a for executing the algorithm. In this example implementation, the observer circuit 500a has a full parallel observer architecture. The observer circuit 500a may be implemented as an analog circuit or as a digital circuit. In this first example implementation, the observer circuit 500a is combinatory and operations are performed concurrently.

FIG. 5B is a diagram of single stream observer architecture 500b for implementing the observer circuit. In this example implementation, the single stream observer architecture 500b may be implemented as a small state machine feeding a multiplier/multiplier+accumulator unit. In this example implementation, the observer circuit 124 is implemented as a digital circuit. In alternative embodiments, it may be implemented as an analog circuit. In this second example implementation, the single stream observer architecture 500b solves the equations step by step in a sequential manner, performing one operation at a time. For example, during cycle 0, the architecture 500b determines if 0 or B_{obs11_B} are loaded into the accumulator register of the multiplier/accumulator unit. Then during the next cycle, if B_{obs11_B} has been loaded then this value is added to the accumulator.

FIG. 5C is a diagram of a dual stream observer architecture 500c for implementing the observer circuit. In this example implementation, the single stream observer architecture 500c may be implemented as a small state machine feeding a multiplier/multiplier+accumulator unit. In this example implementation, the observer circuit 124 is implemented as a digital circuit. In alternative embodiments, it may be implemented as an analog circuit. In this third example implementation, the dual stream observer architecture 500c solves equations step by step in a sequential manner, performing one operation at a time.

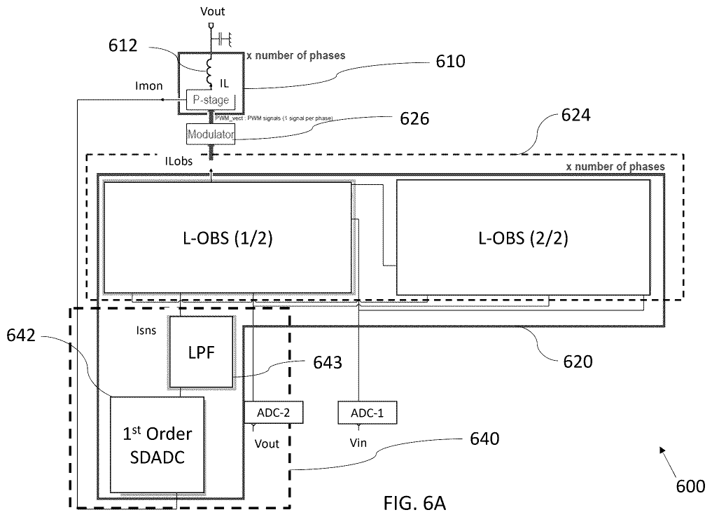

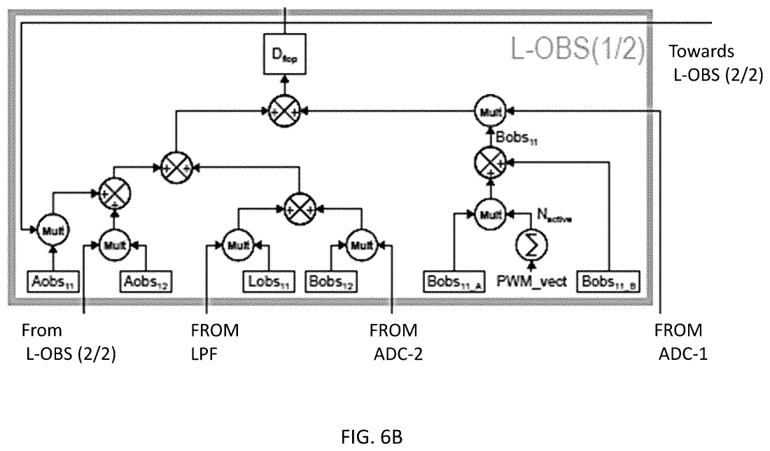

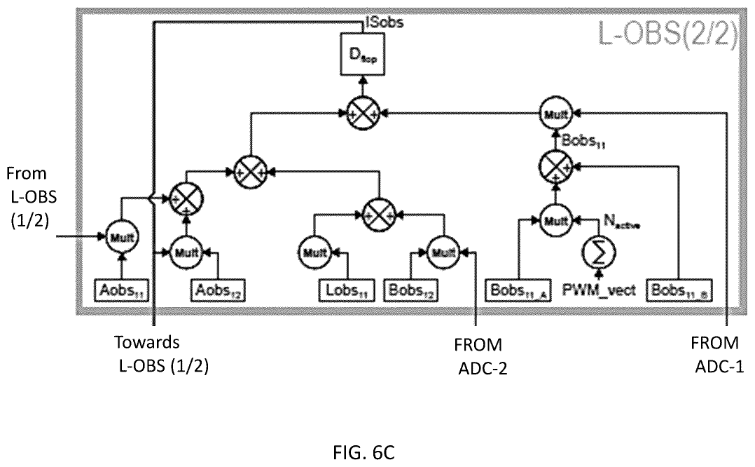

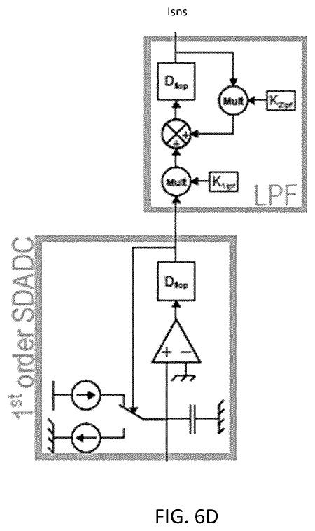

FIG. 6A is an exemplary implementation of a power circuit 600 according to the present disclosure. The power circuit 600 comprises one or more power supplies 610 (also referred to as phase) and a controller 620. Each power supply 610 comprises an inductor 612 and a sensor (not shown) configured to sense a first inductor current Iₘₒₙ. The first inductor current Iₘₒₙ has a first bandwidth. The controller 620 is configured to control the one or more power supplies 610. The controller 620 comprises a SDADC 640 and a calculator or observer circuit 624 for executing the algorithm.

In operation, the sensor senses the first inductor current Iₘₒₙ and transmits this to the controller 620. The first inductor current Iₘₒₙ is received at the SDADC 640 which is configured to filter the first inductor current Iₘₒₙ to generate a filtered inductor current Iₛₙₛ. The filtered inductor current has a second bandwidth which is less than the first bandwidth. The SDADC 640 comprises a first order sigma delta modulator 642 and a low pass filter 643. The controller is then configured to process the filtered inductor current Iₛₙₛ to generate an estimated inductor current I_{obs} having a third bandwidth which is greater than the second bandwidth. The controller processes the filtered inductor current Iₛₙₛ using an algorithm based on an observer model. In this example algorithm based on an Luenberger observer is executes using a digital circuit with parallel architecture. The third bandwidth of the estimated inductor current I_{obs} may be equal to the first bandwidth of the first inductor current Iₘₒₙ. In such cases, the estimated inductor current I_{obs} is a reconstruction of the first inductor current Iₘₒₙ. The estimated inductor current I_{obs} is then passed through a modulator 626 which generates the control signals for the one or more power supplies 610. In this exemplary power circuit 600, the modulator 626 is a PWM modulator.

Whilst in this exemplary power circuit 600, the SDADC 640 is shown as part of the controller 620, in alternative embodiments the SDADC 640 may be implemented elsewhere in the power circuit 600. For instance, it may be implemented as part of the one or more power stages 610.

FIGS. 6B and 6C show an exemplary implementation of the calculator/observer circuit 624 of FIG. 6A. The observer circuit 624 is implemented as a digital circuit having a parallel architecture made of a first circuit L-OBS (1/2) shown in FIG. 6B and a second circuit L-OBS (2/2) shown in FIG. 6C.

FIG. 6D is an example implementation of a filter for use in the system of FIG. 6A.

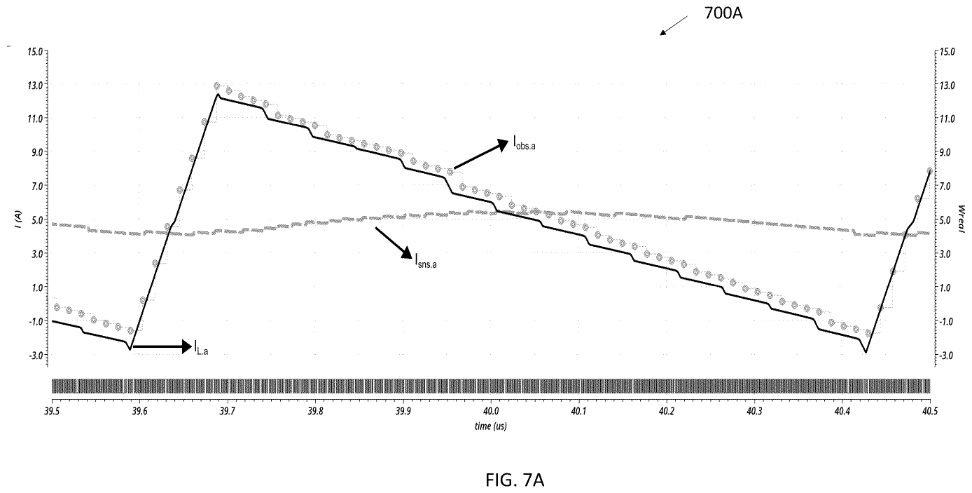

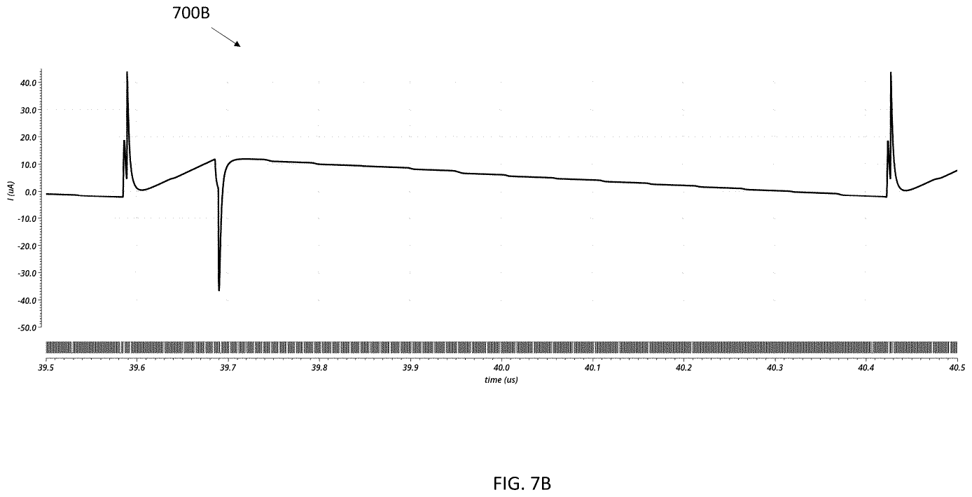

FIG. 7A is a plot 700A showing simulation results for a power circuit comprising the single stream observer architecture 500b of FIG. 5B. The plot 700A shows the estimated inductor current I_{obs,a}, the filtered inductor current I_{sns,a} and the actual inductor current I_{L_a}.

FIG. 7B is a plot 700B showing the current fed back by the power-stage model. In plot 700B, the current contains noise.

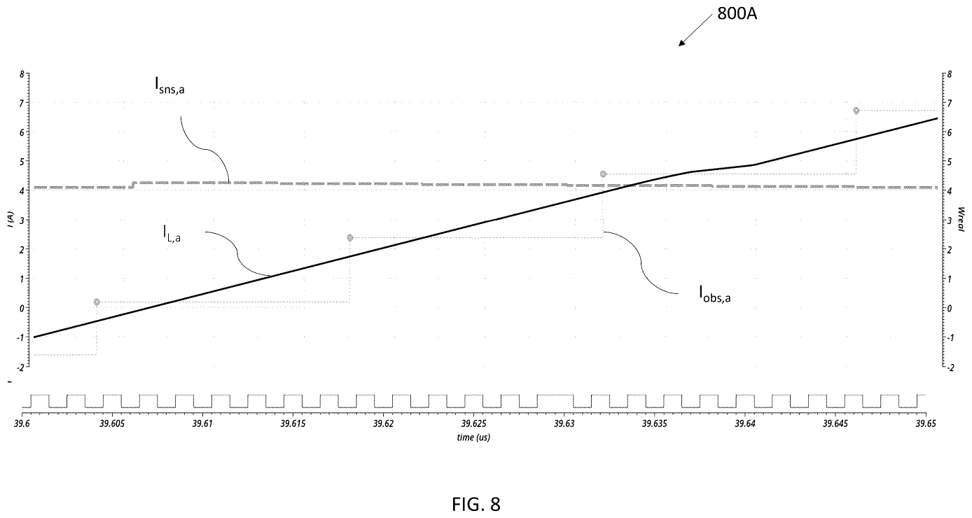

FIG. 8 is a plot 800A showing simulation results for a power circuit comprising the single stream observer architecture 500b for FIG. 5B. The plot 800A shows the estimated inductor current I_{obs,a}, the filtered inductor current I_{sns,a} and the actual inductor current I_{L_a}.

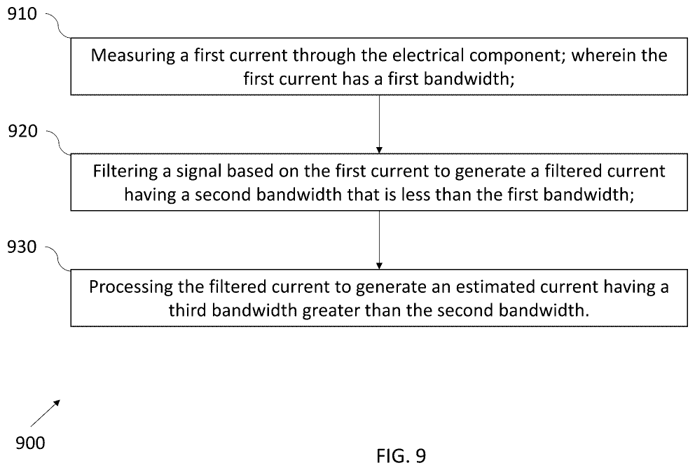

FIG. 9 is a flow chart of a method 900 of estimating a current through an electrical component adapted to store energy, such as an inductor. The method may be implemented using the power circuits 100 or 600″ described above.

At step 910, a first current is measured through the electrical component. The first current has a first bandwidth. Then at step 920 a signal based on the first current is filtered to generate a filtered current having a second bandwidth. The signal based on the first inductor current may be the measured first inductor current itself.

The second bandwidth is less than the first bandwidth. The filtering may be performed using a low pass filter. The low pass filter may comprise a sigma-delta analogue-to-digital converter. At step 930, the filtered current is processed to generate an estimated current. The estimated current has a third bandwidth greater than the second bandwidth. The third bandwidth may be equal to the first bandwidth. The processing of the filtered current may be performed by executing an algorithm based on an observer model.

The power circuit and method of the present disclosure may be applied for different applications including for dense power distribution systems or other high-power systems, to name a few.

A skilled person will appreciate that variations of the disclosed arrangements are possible without departing from the disclosure. Accordingly, the above description of the specific embodiments is made by way of example only and not for the purposes of limitation. It will be clear to the skilled person that minor modifications may be made without significant changes to the operation described.

1. A power circuit comprising:
one or more power supplies, wherein each power supply comprises an electrical component adapted to store energy;
a controller for controlling the one or more power supplies;
a sensor adapted to sense a first current through the electrical component, wherein the first current has a first bandwidth; and
a filter configured to receive a signal based on the first current and output a filtered current having a second bandwidth that is less than the first bandwidth;
wherein the controller is configured to process the filtered current to generate an estimated current having a third bandwidth greater than the second bandwidth.

2. The power circuit as claimed in claim 1, wherein the filter is a low pass filter.

3. The power circuit as claimed in claim 2, wherein the low pass filter has a transfer function characterised by a pole at a predefined frequency and designed to attenuate parasitic noise present in the power circuit.

4. The power circuit as claimed in claim 3, wherein the power circuit has parasitic poles having parasitic frequencies, and wherein the pole associated with the low pass filter is a dominant pole having a frequency lower than the parasitic frequencies.

5. The power circuit as claimed in claim 4, wherein the dominant pole is configured to set the cutoff frequency so that the parasitic frequencies can be neglected.

6. The power circuit as claimed in claim 3, wherein the predefined frequency of the pole is selected to be about 5 to 10 times slower than a switching frequency of the first current.

7. The power circuit as claimed in claim 2, wherein the low pass filter comprises a sigma-delta analogue-to-digital converter.

8. The power circuit as claimed in claim 7, wherein the low pass filter comprises an anti-aliasing filter coupled to the sigma-delta analogue-to-digital converter.

9. The power circuit as claimed in claim 1, wherein the first current comprises a noise component, the noise component comprising noise arising from one or more sources in the power circuit.

10. The power circuit as claimed in claim 1, wherein the third bandwidth is equal to the first bandwidth.

11. The power circuit as claimed in claim 1, wherein the controller is configured to execute an algorithm based on an observer model.

12. The power circuit as claimed in claim 11, wherein the observer model is configured using a set of data points; wherein the set of data points comprises one or more of: parameters of the filter, properties of the one or more power supplies, an input voltage for the one or more power supplies, and an output voltage for the one or more power supplies.

13. The power circuit as claimed in claim 11, wherein the observer model comprises a Luenberger observer model or a sliding-mode observer.

14. The power circuit as claimed in claim 1, wherein the controller comprises a calculator for executing the algorithm, wherein the calculator is implemented with a parallel architecture, or a single stream observer architecture, or a dual stream observer architecture.

15. The power circuit as claimed in claim 1, wherein the electrical component comprises an inductor, and wherein the first current is a first inductor current, the filtered current is a filtered inductor current, and the estimated current is an estimated inductor current.

16. A method of estimating a current through an electrical component adapted to store energy, the method comprising:
measuring a first current through the electrical component, wherein the first current has a first bandwidth;
filtering a signal based on the first current to generate a filtered current having a second bandwidth that is less than the first bandwidth; and
processing the filtered current, to generate an estimated current having a third bandwidth greater than the second bandwidth.

17. The method of claim 16, wherein the third bandwidth is equal to the first bandwidth.

18. The method of claim 16, wherein processing the filtered current comprises executing an algorithm based on an observer model.

19. The method of claim 16, wherein the filtering is performed using a low pass filter having a transfer function characterised by a pole at a predefined frequency and designed to attenuate parasitic noise present in the power circuit.

20. The method of claim 19, wherein the low pass filter comprises a sigma-delta analogue-to-digital converter.
